(19) United States
(12) Patent Application Publication
(10) Pub. No.: US 2023/0110167 A1
(43) Pub. Date: Apr. 13, 2023

(54) SEMICONDUCTOR LASER DEVICE

(71) Applicant: Panasonic Holdings Corporation, Osaka (JP)

(72) Inventor: Hideo YAMAGUCHI, Kyoto (JP)

(21) Appl. No.: 17/796,163

(22) PCT Filed: Jan. 22, 2021
(86) PCT No.: PCT/JP2021/002329

§ 371 Date: Jul. 28, 2022

(30) Foreign Application Priority Data
Feb. 3, 2020 (JP) 2020-016225

(51) Int. Cl. H01S 5/02253; H01S 5/14; H01S 5/40; H01S 5/023

(52) U.S. Cl. CPC H01S 5/02253; H01S 5/143; H01S 5/4025; H01S 5/023

(57) ABSTRACT

A semiconductor laser device includes: a semiconductor laser element; a lower base provided with the semiconductor laser element; an upper base that is electrically insulated from the lower base, and sandwiches the semiconductor laser element together with the lower base; a lens that allows laser light that has exited from semiconductor laser element to enter, concentrates the laser light that has entered, and allows the laser light that has been concentrated to exit; and a holder that holds the lens. The holder is connected to the upper base.

### CROSS-REFERENCE OF RELATED APPLICATIONS

This application is the U.S. National Phase under 35 U.S.C. § 371 of International Patent Application No. PCT/JP2021/002329, filed on Jan. 22, 2021, which in turn claims the benefit of Japanese Patent Application No. 2020-016225, filed on Feb. 3, 2020, the entire disclosures of which Applications are incorporated by reference herein.

### TECHNICAL FIELD

The present disclosure relates to a semiconductor laser device.

### BACKGROUND ART

Conventionally, semiconductor laser devices that include a semiconductor laser element that emits laser light and an optical member such as a lens which controls distribution and the like of the laser light are available (for example, see Patent Literature (PTL) 1 and PTL 2).

Semiconductor devices disclosed in PTL 1 and PTL 2 each include a semiconductor laser array that emits laser light, a condenser lens, a lens holder, and a heat sink. The condenser lens and the lens holder adhere to the heat sink.

### CITATION LIST

### Patent Literature

[PTL 1] Japanese Unexamined Patent Application Publication No. 2002-232064
[PTL 2] Japanese Unexamined Patent Application Publication No. 2004-200634
[PTL 3] Japanese Unexamined Patent Application Publication No. 2000-137139

### SUMMARY OF INVENTION

### Technical Problem

When a light source such as a semiconductor laser array emits light, the light source produces heat. Moreover, the light source and a base or the like on which the light source is placed expand due to the heat produced by the light source. Accordingly, when the light source emits light, the position of the light that passes through an optical system such as a condenser lens is displaced from a desired position. This presents a problem of displacing the optical axis of light (e.g., laser light) that is emitted from a semiconductor laser device from a desired position according to an amount of light emitted from the light source, or in other words, according to an amount of electric power input to the light source for the light source to emit light.

The present disclosure provides a semiconductor laser device that can maintain a relative positional relationship between a semiconductor laser element that emits laser light and a lens that concentrates the laser light.

### Solution to Problem

A semiconductor laser device according to one aspect of the present disclosure includes: a semiconductor laser element that includes a plurality of light exiting points from each of which laser light exits; a lower base provided with the semiconductor laser element; an upper base that is electrically insulated from the lower base, and sandwiches the semiconductor laser element together with the lower base; a lens that allows laser light that has exited from each of the plurality of light exiting points to enter, concentrates the laser light that has entered, and allows the laser light that has been concentrated to exit; and a holder that holds the lens, wherein the holder is connected to the upper base.

### Advantageous Effects of Invention

A semiconductor laser device according to an aspect of the present disclosure can maintain a relative positional relationship between a semiconductor laser element that emits laser light and a lens that concentrates the laser light.

### BRIEF DESCRIPTION OF DRAWINGS

FIG. 1 is a schematic diagram schematically illustrating a configuration of a semiconductor laser device according to an embodiment.

FIG. 2 is a perspective view of a light source module included in the semiconductor laser device according to the embodiment.

FIG. 3 is a perspective view of the light source module included in the semiconductor laser device according to the embodiment in a state in which a lens and a holder are not provided.

FIG. 4 is a cross sectional view of the light source module included in the semiconductor laser device according to the embodiment which is taken along line IV-IV shown in FIG. 2.

FIG. 5 is a top view of the light source module included in the semiconductor laser device according to the embodiment.

FIG. 6 is a graph showing amounts of change in positions of the semiconductor laser element and an upper base with respect to electric currents applied to the semiconductor laser element.

FIG. 7 is a cross sectional view of a semiconductor laser device according to a variation.

### DESCRIPTION OF EMBODIMENT

Hereinafter, an embodiment of a semiconductor laser device according to the present disclosure will be described based on the drawings. Note that all of the embodiments disclosed below are mere examples; therefore, the embodiments are not intended to place limitations on the semiconductor laser device according to the present disclosure. The numerical values, shapes, materials, structural elements, the arrangement and connection of the structural elements, steps, orders of the steps, etc. presented in the embodiment below are mere examples, and are not intended to limit the present disclosure.

Moreover, in the embodiments disclosed below, unnecessarily detailed description may be omitted. For example, detailed description on items already widely known, and redundant description on substantially the same configuration may be omitted. This is to facilitate understanding by those skilled in the art by avoiding unnecessarily redundant description.

In addition, the drawings are schematic diagrams and do not necessarily provide strictly accurate illustrations. Therefore, scales and the like of the drawings do not necessarily coincide with one another. Throughout the drawings, the same numeral is given to substantially the same element, and redundant description on substantially the same element may be omitted or simplified.

In the embodiments below, terms “upper/above” and “lower/below” do not define an upward direction (vertically upward) and a downward direction (vertically downward) in absolute spatial cognition. Moreover, the terms “upper/above” and “lower/below” apply, not only to a case where two structural elements are disposed spaced apart with another structural element interposed between the two structural elements, but also to a case where two structural elements are disposed adhering to each other and in contact with each other.

In the present description and drawings, the X axis, Y axis, and Z axis represent three axes in a three-dimensional orthogonal coordinate system. In each embodiment, the Z-axis direction indicates the vertical direction, and a direction perpendicular to the Z axis (a direction parallel to the X-Y plane) indicates the horizontal direction.

Moreover, a “top view” in the embodiments described below indicates a view of a placement surface (principal surface) of a base on which a light source is placed from a direction normal to the placement surface.

### Embodiment

### [Overall Configuration]

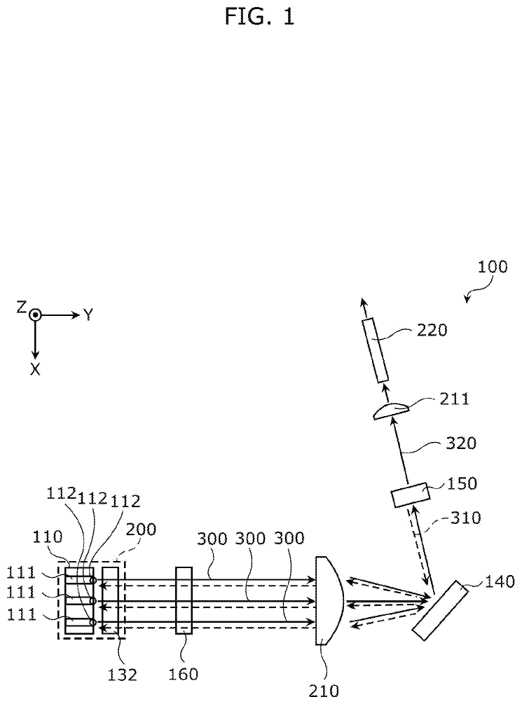

FIG. 1 is a diagram schematically illustrating a configuration of semiconductor laser device 100 according to an embodiment.

Semiconductor laser device 100 is a laser device that emits laser light. Semiconductor laser device 100 is used as, for example, a light source of a machining device that performs laser light machining on an object.

Semiconductor laser device 100 includes, for example, light source module 200, slow axis collimator lens (SAC) 160, condenser lens 210, wavelength dispersing element 140, half mirror 150, condenser lens 211, and optical fiber 220.

Light source module 200 is a light source that emits light (emitted light 300). In this embodiment, light source module 200 includes semiconductor laser element 110 including a plurality of amplifiers 111. Accordingly, semiconductor laser element 110 emits a plurality of beams of emitted light 300 from a plurality of light exiting points 112 corresponding to a plurality of amplifiers 111. Emitted light 300 is, for example, laser light.

Moreover, light source module 200 includes beam twisted lens unit (BTU) 132 that allows emitted light 300 emitted by semiconductor laser element 110 to pass through. BTU 132 is an optical element that concentrates (more specifically, collimates) emitted light 300, and causes emitted light 300 to rotate 90 degrees about the optical axis of emitted light 300. BTU 132 includes, for example, a fast axis collimator (FAC) lens that collimates the fast axis direction of emitted light 300 emitted by semiconductor laser element 110. In this embodiment, two lenses, which are the FAC lens and condenser lens 210, are used to collimate the fast axis direction of emitted light 300. Note that semiconductor laser device 100 need not include condenser lens 210.

The slow axis direction of emitted light 300 that has exited from BTU 132 is collimated by slow axis collimator lens 160, and then enters condenser lens 210.

Condenser lens 210 is a fast axis collimator lens that collimates the fast axis direction of emitted light 300 that has entered.

Condenser lens 210 collimates the fast axis direction of emitted light 300 that has entered, and causes emitted light 300 to enter wavelength dispersing element 140. In this embodiment, semiconductor laser element 110 emits emitted light 300 such that emitted light 300 travels in the Z axis direction that is the fast axis direction and the X axis direction that is the slow axis direction.

Wavelength dispersing element 140 is an optical element that allows emitted light 300 to enter. Wavelength dispersing element 140 allows a plurality of beams of emitted light 300 that have entered to exit such that the plurality of beams of emitted light 300 pass through one optical path. In other words, wavelength dispersing element 140 is a multiplexer that multiplexes emitted light 300. Wavelength dispersing element 140 includes a diffraction grating that is disposed on a surface through which emitted light 300 enters, for example. Emitted light 300 enters through the diffraction grating disposed on the surface of wavelength dispersing element 140, and is exited from wavelength dispersing element 140 such that emitted light 300 passes through one optical path, for example. The light exited from wavelength dispersing element 140 so as to pass through one optical path enters half mirror 150. Wavelength dispersing element 140 may be a transmissive-type wavelength dispersing element that allows a plurality of beams of emitted light 300 to pass through to multiplex the plurality of beams of emitted light 300, or may be a reflective-type wavelength dispersing element that reflects a plurality of beams of emitted light 300 to multiplex the plurality of beams of emitted light 300.

Half mirror 150 allows part of emitted light 300 emitted by semiconductor laser element 110 to pass through and reflects the rest to resonate emitted light 300 between semiconductor laser element 110 and half mirror 150. Reflected light 310 reflected by half mirror 150 travels back to semiconductor laser element 110, is further reflected by semiconductor laser element 110 (specifically, a face on the back side of a light exiting face from which emitted light 300 exits in semiconductor laser element 110), and travels back to half mirror 150. Part of reflected light 310 that has traveled back to half mirror 150 is further reflected by half mirror 150, and travels back to semiconductor laser element 110. With this, optical resonance is produced between semiconductor laser element 110 and half mirror 150. Accordingly, semiconductor laser device 100 emits laser light 320. As described above, semiconductor laser device 100 is an external resonator-type semiconductor laser device that resonates emitted light 300 between semiconductor laser element 110 and half mirror 150. From half mirror 150, laser light 320 produced by an external resonator including semiconductor laser element 110 and half mirror 150 exits. Laser light 320 that has exited from half mirror 150 enters condenser lens 211.

Note that semiconductor laser device 100 need not include an external resonator (more specifically, half mirror 150). Semiconductor laser device 100 may include semiconductor laser element 110 that independently emits laser light.

Condenser lens 211 is a coupling lens for causing laser light 320 to enter optical fiber 220. Laser light 320 that has exited from condenser lens 211 enters optical fiber 220 from one end of optical fiber 220 and exits from the other end of optical fiber 220.

### [Light Source Module]

Next, a configuration of light source module 200 will be described in detail.

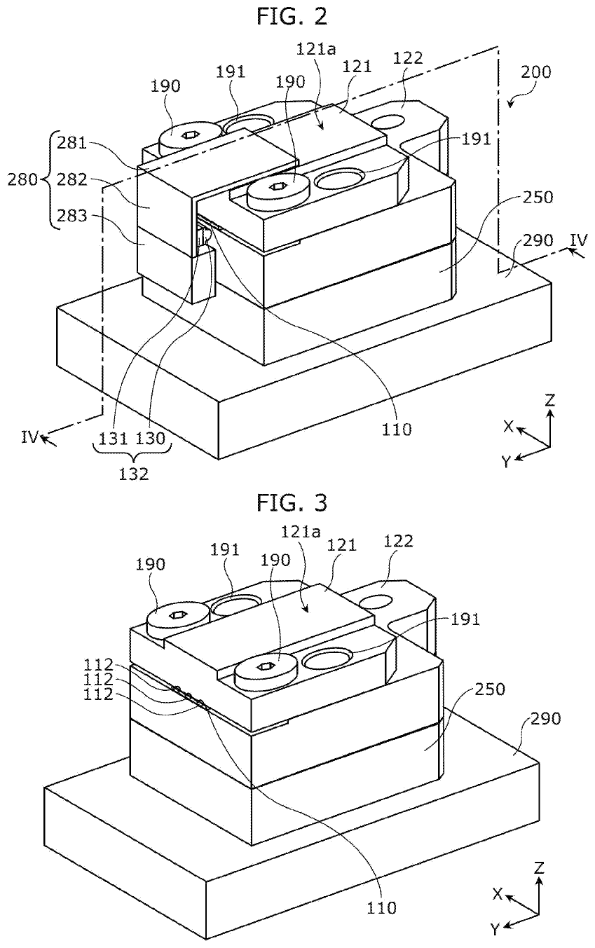

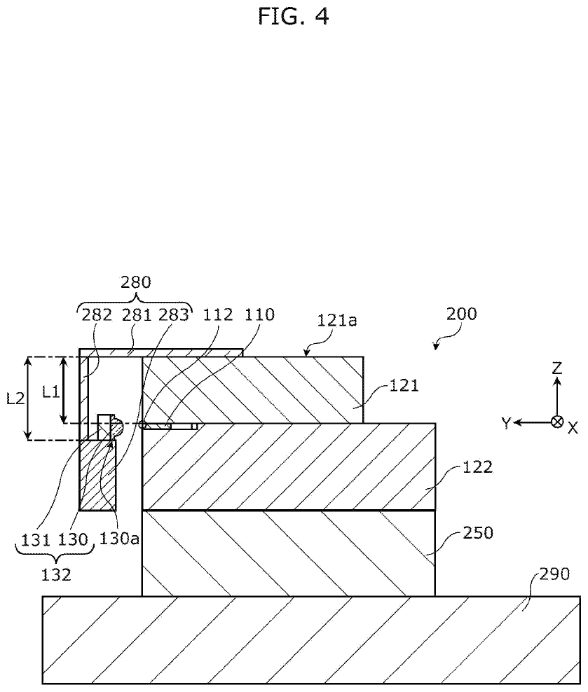

FIG. 2, FIG. 3, and FIG. 4 each are a diagram relating to light source module 200 included in semiconductor laser device 100 according to the embodiment. Specifically, FIG. 2 is a perspective view of light source module 200 included in semiconductor laser device 100 according to the embodiment. FIG. 3 is a perspective view of light source module 200 included in semiconductor laser device 100 illustrated in FIG. 2 in a state in which lens 130 and holder 280 are not provided. FIG. 4 is a cross sectional view of light source module 200 included in semiconductor laser device 100 according to the embodiment which is taken along line IV-IV shown in FIG. 2.

Light source module 200 is a light source that emits emitted light 300.

Light source module 200 includes semiconductor laser element 110, upper base 121, lower base 122, heat sink 250, holder 280, platform 290, and BTU 132.

Semiconductor laser element 110 is a light source that emits emitted light 300.

Note that a wavelength of emitted light 300 to be emitted by semiconductor laser element 110 may be optionally set. In this embodiment, semiconductor laser element 110 emits blue light. Blue light is, for example, light whose center wavelength is at least 430 nm and at most 470 nm. Semiconductor laser element 110 and half mirror 150 together constitute an external resonator. With this, laser light is emitted as emitted light 300 from semiconductor laser element 110.

In this embodiment, semiconductor laser element 110 is a semiconductor laser element array that includes a plurality of amplifiers 111 (see FIG. 1) and emits emitted light 300 from each amplifier 111. In other words, semiconductor laser element 110 includes a plurality of light exiting points 112 from each of which emitted light 300 is exited. As a matter of course, semiconductor laser element 110 may include a plurality of laser elements each including one light exiting point 112.

Note that so long as semiconductor laser device 100 is able to emit laser light as emitted light 300, semiconductor laser device 100 need not include structural elements for constituting an external resonator, such as half mirror 150 shown in FIG. 1. Moreover, a material to be used for semiconductor laser element 110 is not particularly limited. Semiconductor laser element 110 is, for example, a gallium nitride-based semiconductor element.

Semiconductor laser element 110 emits emitted light 300 by supply of electric power from an external commercial power supply or the like which is not illustrated.

Semiconductor laser element 110 is provided at and fastened to the top surface of lower base 122 by, for example, brazing, soldering, or the like. In addition, semiconductor laser element 110 is fastened in a configuration in which semiconductor laser element 110 is interposed between upper base 121 and lower base 122.

Holder 280 is a member that holds (supports) BTU 132 (more specifically, lens 130 included in BTU 132). Holder 280 is connected (fastened) to top surface 121a of upper base 121 by, for example, brazing, soldering, or the like. In this embodiment, holder 280 is of a U shape in a side view. More specifically, holder 280 is of a U shape when seen from a direction orthogonal to the optical axis of emitted light 300 and from a side of light source module 200.

Holder 280 includes, for example, holder upper member 281, holder lower member 282, and holder supporting member 283. Holder upper member 281, holder lower member 282, and holder supporting member 283 are connected together in the stated order.

Note that holder upper member 281, holder lower member 282, and holder supporting member 283 may be integrally formed, or may be individual members that are connected using a screw, adhesive, or the like.

Holder upper member 281 is of a plate-like shape, and is fastened to top surface 121a of upper base 121. For example, holder upper member 281 is fastened to top surface 121a of upper base 121 with a screw, adhesive, or the like which is not illustrated. In addition, holder upper member 281 is connected with holder lower member 282 at an end portion on the positive side of the Y axis direction. A material to be used for holder upper member 281 is not particularly limited.

Holder lower member 282 is of a plate-like shape, and extends from the end portion of holder upper member 281 to the negative side of the Z axis direction. Holder lower member 282 is, for example, a member including a light-transmissive material such as quartz. With this, emitted light 300 emitted by semiconductor laser element 110 passes through lens 130 and holder lower member 282, and exits from light source module 200.

Note that holder lower member 282 need not be light-transmissive. In this case, holder lower member 282 includes a through hole through which emitted light 300 that has exited from lens 130 (BTU 132) passes, for example. A material to be used for holder lower member 282 in this case is not particularly limited.

Holder lower member 282 is connected with holder supporting member 283 at an end portion on the negative side of the Z axis direction.

Holder supporting member 283 is a holding base that holds BTU 132 (more specifically, lens 130). In this embodiment, holder supporting member 283 is a parallelepiped, and extends from the end portion of holder lower member 282 on the negative side of the Z axis direction to the negative side of the Y axis direction. Moreover, the top surface of holder supporting member 283 and bottom surface 130a of lens 130 are fastened together. In other words, holder 280 (more specifically, holder supporting member 283) holds bottom surface 130a of lens 130.

In addition, holder 280 may include an adjustment mechanism for holding lens 130 and adjusting the position and orientation of lens 130. In this embodiment, the adjustment mechanism is holder supporting member 283. Holder supporting member 283 is, for example, a goniometer stage or a stage capable of adjusting six axes. If holder supporting member 283 is not an adjustment mechanism, holder supporting member 283 may be a block including an optional material.

Moreover, the length of holder upper member 281 in the Y axis direction is greater than the length of holder lower member 282 in the Z axis direction. In addition, holder upper member 281 is connected (fastened) to top surface 121a of upper base 121.

Bottom surface 130a of lens 130 is connected to the top surface of holder supporting member 283 by brazing, soldering, or the like. The bottom surface of holder supporting member 283 and heat sink 250 are spaced apart.

Note that it is not inevitably necessary for holder upper member 281 and the top surface of holder supporting member 283 to be parallel to each other. The shape of holder 280 is not particularly limited to the shape described in the embodiment.

In addition, a coefficient of thermal expansion of holder 280 is smaller than a coefficient of thermal expansion of upper base 121, for example.

Upper base 121 is electrically insulated from lower base 122, and is a base that sandwiches semiconductor laser element 110 together with lower base 122.

For example, a thickness (in this embodiment, a width in the Z axis direction) of upper base 121 is denoted as thickness L1, and a length of holder lower member 282 (in other words, a length in the Z axis direction of holder lower member 282, or a length of holder lower member 282 from top surface 121a of upper base 121 to a holding position of lens 130) is denoted as length L2. In this case, light source module 200 is designed such that length L2 is greater than thickness L1. Specifically, holder 280 includes a supporting member that holds lens 130 (holder supporting member 283), and length L2 of holder lower member 282 from top surface 121a of upper base 121 to the holding position of lens 130 is greater than thickness L1 of upper base 121. A direction in which length L2 is measured is parallel to a direction in which thickness L1 is measured, for example.

Lower base 122 is a base provided with semiconductor laser element 110. Semiconductor laser element 110 is provided at the top surface of lower base 122. In this embodiment, a part of the top surface of lower base 122 where semiconductor laser element 110 is placed is lower than the rest of the top surface of lower base 122. Semiconductor laser element 110 is held by lower base 122 such that semiconductor laser element 110 is interposed between upper base 121 and lower base 122.

A material to be used for each of upper base 121 and lower based 122 is not particularly limited. A material to be used for each of upper base 121 and lower base 122 may be a metallic material, a resin material, or a ceramic material, for example.

Moreover, the shape of each of upper base 121 and lower base 122 is not particularly limited.

Upper base 121 and lower base 122 are fastened together with screws 190 fitted into (more specifically, threadedly connected with) screw holes in lower base 122, for example. Specifically, lower base 122 includes the screw holes. In addition, upper base 121 includes through holes at positions corresponding to the screw holes. Screws 190 are provided in the through holes. Screws 190 are threadedly connected with the screw holes.

Note that upper base 121 and lower base 122 may be electrically insulated from each other. For example, an insulating material having electrical insulation characteristics which is not illustrated is disposed between upper base 121 and lower base 122. The insulating material is, for example, an insulating sheet. So long as the insulating sheet has electrical insulation characteristics, an optional material can be used.

In addition, light source module 200 includes through holes that penetrate upper base 121 and lower base 122 and reach to heat sink 250. Screws that are not illustrated are provided in the through holes. With these screws, upper base 121, lower base 122, and heat sink 250 are fastened together.

Moreover, light source module 200 includes two through holes 191. The two through holes 191 are located such that, in a top view, semiconductor laser element 110 is interposed between the two through holes 191 in a direction (the X axis direction in this embodiment) orthogonal to the optical axis of emitted light 300 to be emitted by semiconductor laser element 110, for example. In addition, in the top view, a distance from the center of through hole 191 to semiconductor laser element 110 is the same for both of the two through holes 191, for example.

Heat sink 250 is a base on which lower base 122 of light source module 200 is placed. Heat sink 250 is for dissipating heat of lower base 122. A material to be used for heat sink 250 is not particularly limited. A material to be used for heat sink 250 may be metal or ceramic, for example. In addition, heat sink 250 may be provided with a channel for passing liquid such as water. Flow of liquid such as water through the channel may improve heat dissipation of heat sink 250.

Platform 290 is a base on which heat sink 250 is placed. A material used for platform 290 and a shape of platform 290 are not particularly limited.

BTU 132 is an optical system that concentrates emitted light 300 emitted by semiconductor laser element 110 using lens 130, and causes emitted light 300 that has been concentrated to rotate 90 degrees about the optical axis of emitted light 300 using 90-degrees image rotating optical system 131. The optical luminous flux converter disclosed in Japanese Unexamined Patent Application Publication No. 2000-137139 exemplifies BTU 132. In this embodiment, BTU 132 includes lens 130 and 90-degrees image rotating optical system 131, for example.

Lens 130 is an optical element that allows emitted light 300 that has exited from each of the plurality of light exiting points 112 to enter, concentrates emitted light 300 that has entered, and allows emitted light 300 that has been concentrated to exit. Lens 130 is, for example, a fast axis collimator lens.

The fast axis collimator lens is a collimator lens that collimates the fast axis direction of emitted light 300 emitted by semiconductor laser element 110.

Ninety-degrees image rotating optical system 131 is an optical member that switches between the fast axis direction of emitted light 300 emitted by semiconductor laser element 110 and the slow axis direction of emitted light 300 emitted by semiconductor laser element 110. Specifically, 90-degrees image rotating optical system 131 is an optical element that causes emitted light 300 that has been concentrated (more specifically, collimated) by lens 130 to rotate 90 degrees about the optical axis of the above-mentioned emitted light 300.

For example, lens 130 and 90-degrees image rotating optical system 131 include glass, resin, or the like that is light-transmissive, and are integrally formed.

Note that semiconductor laser device 100 incudes a single BTU 132 in this embodiment, but the shape of BTU 132 and the number of BTUs 132 to be included in semiconductor laser device 100 are not particularly limited.

### [Positional Relationship]

Next, a positional relationship between lens 130 and semiconductor laser element 110 in light source module 200 will be described.

When semiconductor laser element 110 emits emitted light 300, semiconductor laser element 110 produces heat. This production of heat causes upper base 121 to thermally expand, and displaces (changes) upper base 121 in the Z axis direction.

Here, holder upper member 281 is connected to upper base 121. For example, holder upper member 281 is connected to top surface 121a of upper base 121. For this reason, holder 280 displaces in the Z axis direction by only an amount of displacement due to thermal expansion experienced by upper base 121.

Meanwhile, holder 280 also thermally expands due to heat conducted from upper base 121. In this case, holder 280 includes, for example, quartz, and a coefficient of thermal expansion of quartz is smaller than a coefficient of thermal expansion of upper base 121 that includes, for example, metal. For this reason, if holder 280 and upper base 121 have the same width (thickness), an amount of displacement of holder 280 due to thermal expansion is smaller than an amount of displacement of upper base 121 due to thermal expansion.

In this embodiment, since lens 130 is connected to the top surface of holder supporting member 283, length L2 that is a length from top surface 121a to the holding position (in this embodiment, bottom surface 130a of lens 130) of lens 130 at holder supporting member 283 can be extended greater than thickness L1 that is a thickness of upper base 121. Consequently, an amount of displacement of holder lower member 282 in the Z axis direction due to thermal expansion can be approximated to an amount of displacement of upper base 121 due to thermal expansion.

Therefore, according to semiconductor laser device 100 (more specifically, light source module 200), it is possible to suppress a change in a relative positional relationship between semiconductor laser element 110 and lens 130 in the Z axis direction, before and after thermal expansion is experienced by each of semiconductor laser element 110, upper base 121, and holder 280.

Since a material of holder 280 and a length of holder lower member 282 have a degree of freedom in terms of design, a design change can be made such that displacement of a relative positional relationship between semiconductor laser element 110 and lens 130 in the Z axis direction before and after thermal expansion is zero.

Furthermore, upper base 121 is connected with lower base 122 so as to sandwich semiconductor laser element 110 together. For this reason, neither semiconductor laser element 110 nor lens 130 displace in the X axis direction due to thermal expansion. With this, a space between semiconductor laser element 110 and lens 130 in the X axis direction is kept constant.

Moreover, a configuration in which holder 280 is of a U shape and lens 130 is connected to the top surface of holder supporting member 283 can suppress the load on a connecting portion between holder 280 and lens 130 in the gravity direction. Accordingly, lens 130 can be more stably held.

### [Advantageous Effects, Etc.]

As has been described above, semiconductor laser device 100 according to the embodiment includes: semiconductor laser element 110 that includes a plurality of light exiting points 112 from each of which laser light (emitted light 300) exits; lower base 122 provided with semiconductor laser element 110; upper base 121 that is electrically insulated from lower base 122, and sandwiches semiconductor laser element 110 together with lower base 122; lens 130 that allows emitted light 300 that has exited from each of plurality of light exiting points 112 to enter, concentrates emitted light 300 that has entered, and allows emitted light 300 that has been concentrated to exit; and holder 280 that holds lens 130. Holder 280 is connected to upper base 121. For example, holder upper member 281 is connected to top surface 121a of upper base 121.

With this, as described above, an amount of displacement of semiconductor laser element 110 due to thermal expansion can be equivalent to an amount of displacement of upper base 121 due to thermal expansion, even if semiconductor laser element 110 and upper base 121 thermally expand due to heat produced by semiconductor laser element 110. For this reason, according to semiconductor laser device 100, it is possible to maintain a relative positional relationship between semiconductor laser element 110 that emits laser light and lens 130 that concentrates the laser light.

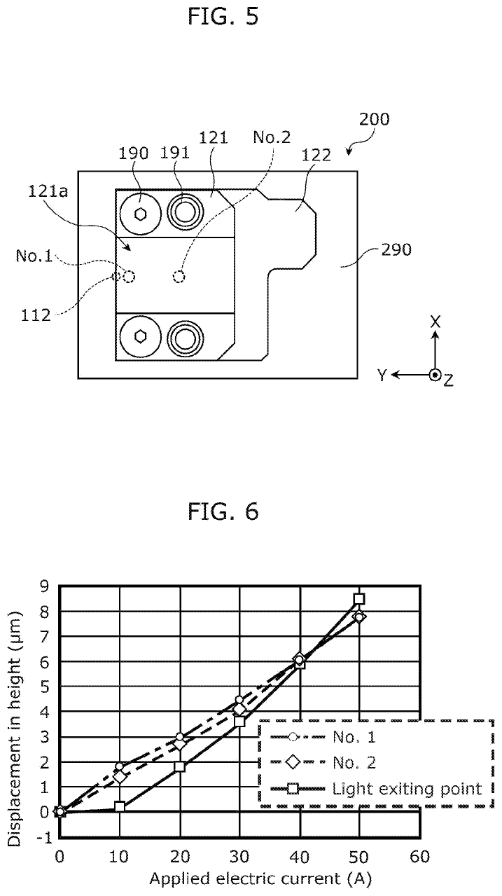

FIG. 5 is a top view of light source module 200 included in semiconductor laser device 100 according to the embodiment. FIG. 6 is a graph showing amounts of change (amounts of displacement) in positions of semiconductor laser element 110 and upper base 121 with respect to electric currents applied to semiconductor laser element 110. Specifically, FIG. 6 is a graph showing amounts of displacement in height (in this embodiment, Z axis direction) at each of a position denoted by No. 1 at top surface 121a shown in FIG. 5, a position denoted by No. 2 at top surface 121a shown in FIG. 5, and a position of light exiting point 112, with respect to electric currents applied to semiconductor laser element 110.

As illustrated in FIG. 6, an amount of displacement of each of the position denoted by No. 1 at top surface 121a shown in FIG. 5, the position denoted by No. 2 at top surface 121a shown in FIG. 5, and the position of light exiting point 112 in a height direction (Z axis direction) with respect to an electric current applied to semiconductor laser element 110 changes in a similar manner. For this reason, regardless of an application of an electric current to semiconductor laser element 110, it is possible to maintain a relative positional relationship between semiconductor laser element 110 that emits laser light and lens 130 that concentrates the laser light. Particularly, semiconductor laser element 110 is the so-called multi emitter including a plurality of light exiting points 112. Since the total output of laser light produced by semiconductor laser element 110 including a plurality of light exiting points 112 tends to be large compared to the so-called single emitter that is a semiconductor laser element including a single light exiting point, an amount of heat produced by semiconductor laser element 110 tends to be large. For this reason, semiconductor laser device 100 having a configuration where a relative positional relationship between semiconductor laser element 110 and lens 130 can be maintained even laser light is emitted by semiconductor laser element 110 is particularly effective for a configuration where semiconductor laser device 100 includes semiconductor laser element 110 that includes a plurality of light exiting points 112.

Moreover, a coefficient of thermal expansion of holder 280 is smaller than a coefficient of thermal expansion of upper base 121.

As described above, an amount of displacement of semiconductor laser element 110 can be equivalent to an amount of displacement of upper base 121 by making holder 280 resistant to thermal expansion. Accordingly, a relative positional relationship between semiconductor laser element 110 that emits laser light and lens 130 that concentrates the laser light can be maintained.

In addition, holder 280 includes a supporting member (holder supporting member 283) that holds lens 130, for example. For example, a length of holder 280 (length L2 of holder lower member 282) from top surface 121a of upper base 121 to a holding position of lens 130 is greater than thickness L1 of upper base 121.

With this, a relative positional relationship between semiconductor laser element 110 that emits laser light and lens 130 that concentrates the laser light can be further readily maintained.

Moreover, holder 280 is of a U shape in a side view, for example. In addition, holder 280 holds bottom surface 130a of lens 130, for example.

According to the above, holder 280 can hold lens 130 from the gravity direction side on which gravity acting on lens 130 is acted, compared to the case where lens 130 is held via the top surface or a side face of lens 130. For this reason, lens 130 can be further stably held while maintaining a relative positional relationship between semiconductor laser element 110 and lens 130.

In addition, holder 280 includes an adjustment mechanism for holding lens 130 and adjusting a position and an orientation of lens 130, for example.

With this, a position and an orientation of lens 130 can be adjusted to appropriate states, and the position and the orientation of lens 130 can be fixed.

### [Variation]

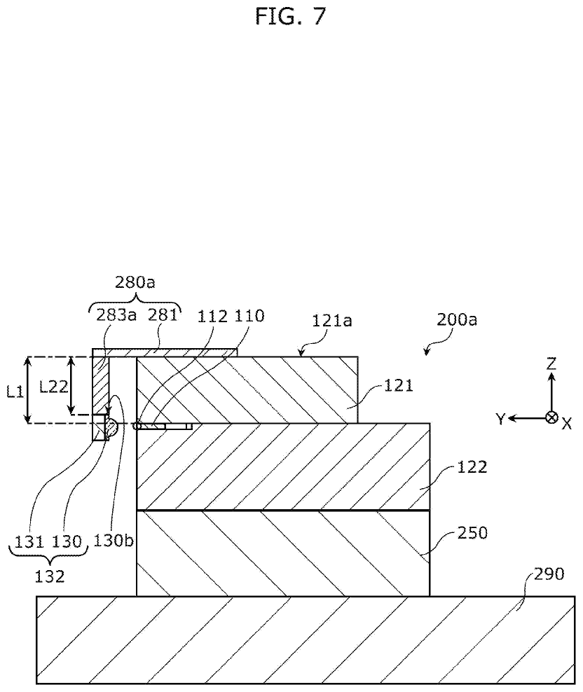

FIG. 7 is a cross sectional view of light source module 200a included in a semiconductor laser device according to a variation. Note that a cross section shown in FIG. 7 corresponds to a cross section shown in FIG. 4.

Light source module 200a is different from light source module 200 in the shape of a holder and a holding position of lens 130.

Light source module 200a is a module that emits laser light (e.g., emitted light 300 shown in FIG. 1).

Light source module 200a includes semiconductor laser element 110, upper base 121, lower base 122, heat sink 250, holder 280a, platform 290, and BTU 132.

Holder 280a is connected to top surface 121a of upper base 121 by, for example, brazing, soldering, or the like. In this variation, holder 280a is of an L shape in a side view. Specifically, holder 280a is of an L shape including holder upper member 281 and holder supporting member 283a. More specifically, holder 280 is of an L shape when seen from a direction orthogonal to the optical axis of laser light emitted by semiconductor laser element 110 and from a side of light source module 200a. Holder upper member 281 and holder supporting member 283a are connected with each other.

Holder upper member 281 is of a plate-like shape, and is fastened to top surface 121a of upper base 121. For example, holder upper member 281 is fastened to top surface 121a of upper base 121 with a screw, adhesive, or the like which is not illustrated. Moreover, holder upper member 281 is connected to holder supporting member 283a at an end portion on the positive side of the Y axis direction.

Note that holder upper member 281 and holder supporting member 283a may be integrally formed, or may be individual members that are connected using screws, adhesive, or the like.

Holder supporting member 283a is of a plate-like shape, and extends in the negative side of the Z axis direction from the end portion of holder upper member 281.

A material to be used for holder supporting member 283a is not particularly limited. In addition, holder supporting member 283a may be the above-described adjustment mechanism.

Moreover, a coefficient of thermal expansion of holder 280a is smaller than a coefficient of thermal expansion of upper base 121.

In addition, in this variation, holder 280a holds (supports) top surface 130b of lens 130. Specifically, holder supporting member 283a is connected with top surface 130b of lens 130 thereby holding lens 130 via top surface 130b. For example, top surface 130b of lens 130 is connected to the bottom surface of holder supporting member 283a by brazing, soldering, or the like.

Moreover, length L22 that is a length of holder supporting member 283a from top surface 121a of upper base 121 to the holding position (top surface 130b of lens 130) of lens 130 is less than thickness L1 of upper base 121.

As has been described above, in this variation, holder 280a is of an L shape in a side view. In addition, holder 280a holds top surface 130b of lens 130, for example.

According to the above, the configuration of holder 280a can be more simplified compared to holder 280, while maintaining a relative positional relationship between semiconductor laser element 110 and lens 130.

### Other Embodiments

Hereinbefore, semiconductor laser devices according to embodiments of the present disclosure has been described based on the embodiments, but the present disclosure is not limited to these embodiments. Without departing from the scope of the present disclosure, various modifications which may be conceived by a person skilled in the art, and embodiments achieved by combining structural elements in different embodiments may be encompassed within the range of the one or more aspects of the present disclosure.

### INDUSTRIAL APPLICABILITY

A semiconductor laser device according to the present disclosure is used as a light source of a machining device that is used for laser light machining, for example.

1. A semiconductor laser device comprising:
a semiconductor laser element that includes a plurality of light exiting points from each of which laser light exits;
a lower base provided with the semiconductor laser element;
an upper base that is electrically insulated from the lower base, and sandwiches the semiconductor laser element together with the lower base;
a lens that allows laser light that has exited from each of the plurality of light exiting points to enter, concentrates the laser light that has entered, and allows the laser light that has been concentrated to exit; and
a holder that holds the lens, wherein
the holder is connected to the upper base.

2. The semiconductor laser device according to claim 1, wherein
a coefficient of thermal expansion of the holder is smaller than a coefficient of thermal expansion of the upper base.

3. The semiconductor laser device according to claim 1, wherein
the holder includes a supporting member that holds the lens, and
a length of the supporting member from a top surface of the upper base to a holding position of the lens is greater than a thickness of the upper base.

4. The semiconductor laser device according to claim 3, wherein
the holder is of a U shape in a side view.

5. The semiconductor laser device according to claim 4, wherein
the holder holds a bottom surface of the lens.

6. The semiconductor laser device according to claim 1, wherein
the holder is of an L shape in a side view.

7. The semiconductor laser device according to claim 6, wherein
the holder holds a top surface of the lens.

8. The semiconductor laser device according to claim 1, wherein
the holder includes an adjustment mechanism for holding the lens and adjusting a position and an orientation of the lens.
